(19) United States
(12) Patent Application Publication
(10) Pub. No.: US 2015/0163935 A1
(43) Pub. Date: Jun. 11, 2015

(54) DISPLAY DEVICE EQUIPPED WITH HEIGHT ADJUSTMENT STAND

(71) Applicant: Hiroyuki Kasuga, Tokyo (JP)

(72) Inventor: Hiroyuki Kasuga, Tokyo (JP)

(21) Appl. No.: 14/411,875

(22) PCT Filed: Jul. 5, 2012
(86) PCT No.: PCT/JP2012/067196

§ 371 Date: Dec. 29, 2014

(51) Int. Cl. H05K 5/02

(52) U.S. Cl. CPC H05K 5/0234

(57) ABSTRACT

A display device is equipped with a display having a display screen and a height adjustment stand connected to the display. The height adjustment stand includes a fixed part attached to a stand base, a moving part connected the display and movable up or down inside the fixed part, and a flat cable installed in the fixed part and the moving part. The opposite ends of the flat cable are connected to a lower connector of the fixed part and an upper connector of the moving part, while the flat cable includes an S-shaped curved part at the intermediate point thereof.

### TECHNICAL FIELD

The present invention relates to a display device equipped with a height adjustment stand, e.g. a stand for use in a display device such as a liquid crystal panel having a height adjustment function, which incorporates a wiring cable serving as an electric connection member.

### BACKGROUND ART

In general, plenty of IT devices such as liquid crystal display devices have been recently developed to reduce sizes and weights. In liquid crystal display devices equipped with stands having height adjustment functions, in particular, cables installed in and connected to liquid crystal displays may cause an obstruction of reducing sizes and weights of devices. Plenty of liquid crystal display devices currently available at stores are equipped with height adjustment stands solely including elevating mechanisms, in which a plurality of cables for power supply and signal transmission is wired independently and outside each stand. Thus, it is necessary to develop liquid crystal display devices equipped with stands embedding cables, thus efficiently using external space.

Liquid crystal display devices have been used for cash registers and reception counters easily conspicuous to customer's eyes as well as offices doing general services. Offices should be designed to improve degrees of freedom in terms of layouts by removing fences such as partitions. Since the backs of liquid crystal display devices are conspicuous to human's eyes, cables may be exposed to the exterior in the backs of displays so as to spoil the appearance of devices.

To improve the exterior appearance, it is necessary to commercialize height adjustment stands which prevent cables from being exposed in the exterior of liquid crystal display devices.

For example, Patent Literature Document 1 discloses a liquid crystal display device equipped with a height adjustment stand being currently commercialized. The liquid crystal display device employs a height adjustment stand in which a sliding member can be moved up or down along a support cylinder attached to a stand base as well as a mechanism which is attached to the interconnection between the sliding member and the display panel so as to rotate the display panel to switch between a vertical screen and a horizontal screen. However, it fails to disclose signal transmission cables and a power cable electrically connected between the display panel and the power source.

Patent Literature Document 2 discloses an image display device in which a plurality of through-holes is formed in a stand for use in an image display device storing a television receiver and a peripheral device, wherein the television receiver, the peripheral device, and various connectors are mutually connected together via cables penetrating through through-holes. The stand of an image display device serves as a box incorporating the display screen, the power source, and various signal connectors. Since the stand supporting the display having a display screen is not equipped with an elevation mechanism while cables are installed in a box in advance, it may not cause a negative influence to expose cables to the exterior.

In contrast, FIG. 9 shows a liquid crystal display device equipped with the conventional height adjustment stand, wherein a height adjustment stand 101, made of a support leg equipped with a display panel 100, can be moved up or down. Similar to the conventional device, cables 102 such as a power cable and a signal transmission cable connected to the display panel 100 are installed outside the height adjustment stand 101.

To improve the exterior appearance in another liquid crystal display device, as shown in FIG. 10, the cable 102 is inserted into a cover 105 attached to the height adjustment stand 101 so as to reduce the exposed part. It is necessary to independently install the cover 105 in connection with the height adjustment stand 101 in order to hide the cables 102 not being exposed to the exterior.

Patent Literature Document 3 discloses a head-mount display connected with a cable used to transmit signals to an ear pad from a substrate of a display, wherein the cable is extended from a compartment A to a compartment B which adjoins the compartment A via a partition. When the cable is kept in the compartment A due to looseness of wiring, a wire-winding mechanism using a spring operates to wind up the cable, thus spirally winding up wires. Thus, it is possible to keep wires in the compartment A without being entangled.

### CITATION LIST

### Patent Literature Document

Patent Literature Document 1: Japanese Patent Application Publication No. 2008-301117

Patent Literature Document 2: Japanese Patent Application Publication No. 2006-195217

Patent Literature Document 3: Japanese Patent Application Publication No. 2008-148028

### SUMMARY OF INVENTION

### Technical Problem

The liquid crystal display device shown in FIG. 9 suffers from drawings in which the cables 102 exposed to the exterior may be loosened so as to spoil the exterior appearance when the height adjustment stand 101 is moved up or down and in which the cables 102 may come in contact with the display panel 100 or the stand base 103 so as to damage operability when the display panel 100 is moved up or down.

In the height adjustment stand shown in FIG. 10, it is necessary to independently install the cover 105 used to keep cables in the stand 101 in which the cables 102 are simply inserted through the cover 105. Thus, the height adjustment stand suffers from drawbacks in which the cables 102 exposed to the exterior may be loosened or stretched so as to spoil the exterior appearance when the stand 101 is moved up or down and in which the cables 102 may come in contact with devices so as to degrade operability in moving up or down the stand 101.

The head-mount display of Patent Literature Document 3 can absorb looseness of wires by spirally winding up wires in the compartment A. However, it suffers from a drawback in which it is impossible to smoothly repeat winding and feeding wires since wires spirally wound up in the compartment A may easily interfere with the partition between the compartment A and the compartment B.

Considering the aforementioned circumstances, the present invention aims to provide a display device, equipped with a height adjustment stand providing an appropriate height and exhibiting good exterior appearance, with good operability by preventing wiring cables from interfering with other members irrespective of upward/downward movement.

### Solution to Problem

The present invention is directed to a display equipped with a height adjustment stand, corresponding to a display device including a display having a display screen and a height adjustment stand which is connected to the display so as to carry out height adjustment. The height adjustment stand includes a fixed part attached to a base, a moving part which is connected to the display and movable up or down inside the fixed part, and a wiring cable arranged inside the fixed part and the moving part. The wiring cable has a curved part which is expandable or reducible inside the fixed part and/or the moving part and which is connected between an end of the fixed part and an end of the moving part.

According to the present invention, when the height adjustment stand is elevated so that the moving part having the display ascends up, it is possible to follow an elevation of the moving part with the wiring cable, connected between the end of the moving part and the end of the fixed part, which is being extended with extending the curved part depending on an elevation of the moving part. When the height adjustment stand is reduced in height so that the moving part descends down, it is possible to follow a descending movement of the moving part by adjusting the length of the wiring cable which is being curved at the curved part depending on a descending movement of the moving part. Thus, it is possible to follow the movement by feeding the length of the wiring cable or absorbing the length of the wiring cable due to acceleration of curving at the curved part interposed between the opposite ends depending on the upward/downward movement of the height adjustment stand. Irrespective of an elevation of the height adjustment stand, it is possible to adjust the length of the wiring cable via the curved part serving as a buffering zone. Thus, it is possible to maintain good operability without causing any interference between the wiring cable and other members, and it is possible to exhibit good exterior appearance since the wiring cable is not exposed to the exterior.

It is preferable that the curved part of the wiring cable be an S-shaped curved part or a helically-bent part.

It is possible to follow an elevation of the height adjustment stand with the curved part of the wiring cable corresponding to an S-shaped curved part in which the length of an S-shape can be increased or decreased. It is possible to follow an elevation of the height adjustment stand with the curved part of the wiring cable corresponding to a helically-bent part in which the wound part of a helix is extended or a helix is subjected to multiple winding.

It is preferable that the wiring cable be set to a length leaving the curved part when the moving part is extracted from the fixed part with the maximum length.

Thus, it is possible to prevent a tense condition caused by linearly extending the wiring cable depending on the maximum elevation of the height adjustment stand while securing a room for the curved part; hence, it is possible to prevent the life of the wiring cable from being shortened due to exhaustion of the curved part irrespective of repetition of the upward/downward movement.

It is preferable that the end of the fixed part and the end of the moving part connected to the wiring cable be connectors.

Thus, it is possible to prevent another cable, connected outside the wiring cable, from being changed irrespective of the upward/downward movement of the height adjustment stand; it is possible to prevent another cable from interfering with other members, and it is possible to prevent the exterior appearance from being spoiled. Additionally, the wiring cable is connected between the connectors attached to the opposite ends inside the height adjustment stand; this will not exert a negative influence on an electric connection in the wiring of the height adjustment stand due to the upward/downward movement of the height adjustment stand.

It is preferable that the fixed part and the moving part be connected together via a constant-force spring, thus carrying out height adjustment.

By connecting the fixed part and the moving part together via the constant-force spring, it is possible to extend or reduce the constant-force spring depending on the upward/downward movement of the height adjustment stand, thus stationarily locating the height adjustment stand at an arbitrary position.

It is preferable that the constant-force spring include a spring wound about a drum engaged with the fixed part while the end of the spring is engaged with the moving part.

Since the spring is fed from the drum or wound about the drum engaged with the constant-force spring depending on the upward/downward movement of the height adjustment stand, it is possible to fix an arbitrary position while counterbalancing the spring force with the weights of the display and the moving part.

It is preferable that a plurality of constant-force springs be installed inside the fixed part and the moving part while the wiring cable be aligned between the constant-force springs.

Thus, it is possible to stabilize the extraction or winding of the spring of the constant-force spring at the opposite ends of the wiring cable so as to exert a force on the moving part; hence, it is possible to stabilize the expansion or reduction of the wiring cable while preventing twisting or inclination of the wiring cable.

It is preferable that the end of the moving part be furnished with a first cable electrically connected to the display device while the end of the moving part be furnished with a second cable electrically connected to a power source or a signal supply source.

It is possible to adjust the expansion or reduction of the cable due to the upward/downward movement of the height adjustment stand by use of the wiring cable having the curved part; hence, it is possible to prevent interference with other devices while exhibiting good appearance since the first and second cables, located outside the height adjustment stand, are not extended or reduced in length due to the upward/downward movement of the height adjustment stand.

### Advantageous Effects of Invention

As described above, a display device equipped with a height adjustment stand according to the present invention demonstrates the following effects.

(1) It is unnecessary to arrange cables outside a height adjustment stand because wiring cables are installed inside the height adjustment stand, and therefore it is possible to reduce the size of the height adjustment stand. Additionally, it is unnecessary to provide other components such as a cover used to keep or hide wiring cables, thus improving the exterior appearance.
(2) It is possible to pull out wiring cables from the curved part or to expand or reduce wiring cables due to facilitation of curvature along with the height adjustment stand being moved up or down; it is possible to prevent wiring cables from interfering with the display or the height adjustment stand; and it is possible not to hinder the operability and the upward/downward movement of the height adjustment stand with the display.
(3) It is possible to constantly maintain a first cable, which is exposed in the upper side of a moving part of the height adjustment stand and connected to the display due to the upward/downward movement of the height adjustment stand, and a second cable, which is exposed in the lower side of a fixed part, in terms of the length and the position irrespective of height variations of the height adjustment stand, thus achieving stable upward/downward movement of the height adjustment stand without spoiling the exterior appearance.
(4) Since the opposite ends of wiring cables installed in the height adjustment stand are connected to the end of a moving part and the end of a fixed part, it is possible to stabilize the expansion/reduction and the moving track of wiring cables inside the height adjustment stand being moved up or down without causing kinks of wiring cables due to the height adjustment of the height adjustment stand. This eliminates the necessity of adding components such as cable guides. Thus, it is possible to realize a simple structure.

### BRIEF DESCRIPTION OF DRAWINGS

FIG. 1A is a side view of a liquid crystal display equipped with a height adjustment stand according to the first embodiment of the present invention on the condition that the height adjustment stand is held at an ascending position.

FIG. 1B is a side view of the liquid crystal display of the first embodiment on the condition that the height adjustment stand is held at a descending position.

FIG. 2 includes a front view and an upper view of the height adjustment stand being located at the descending position.

FIG. 3A is a cross-sectional view of the height adjustment stand taken along line A-A in FIG. 2.

FIG. 3B is a cross-sectional view of the height adjustment stand taken along line B-B in FIG. 2.

FIG. 4A is a cross-sectional view of the height adjustment stand being located at the ascending position similar to FIG. 3A.

FIG. 4B is a cross-sectional view of the height adjustment stand being located at the ascending position similar to FIG. 3B.

FIG. 5A is a side view of the display device being located at the ascending position.

FIG. 5B is a side view of the display device being located at the descending position.

FIG. 6A is a cross-sectional view of a liquid crystal display device according to the second embodiment of the present invention with a height adjustment stand being located at the descending position similar to FIG. 3A.

FIG. 6B is a cross-sectional view of the liquid crystal display device according to the second embodiment of the present invention with the height adjustment stand being located at the descending position similar to FIG. 3B.

FIG. 7A is a cross-sectional view of the height adjustment stand being located at the ascending position similar to FIG. 3A.

FIG. 7B is a cross-sectional view of the height adjustment stand being located at the ascending position similar to FIG. 3B.

FIG. 8 is a cross-sectional view showing a variation of the height adjustment stand being descending down.

FIG. 9 includes drawings showing an example of the conventional display device being located at the ascending position and the descending position.

FIG. 10 includes drawings showing another example of the conventional display device being located at the ascending position and the descending position.

### DESCRIPTION OF EMBODIMENTS

Hereinafter, the embodiments of the present invention will be described with reference to the accompanying drawings.

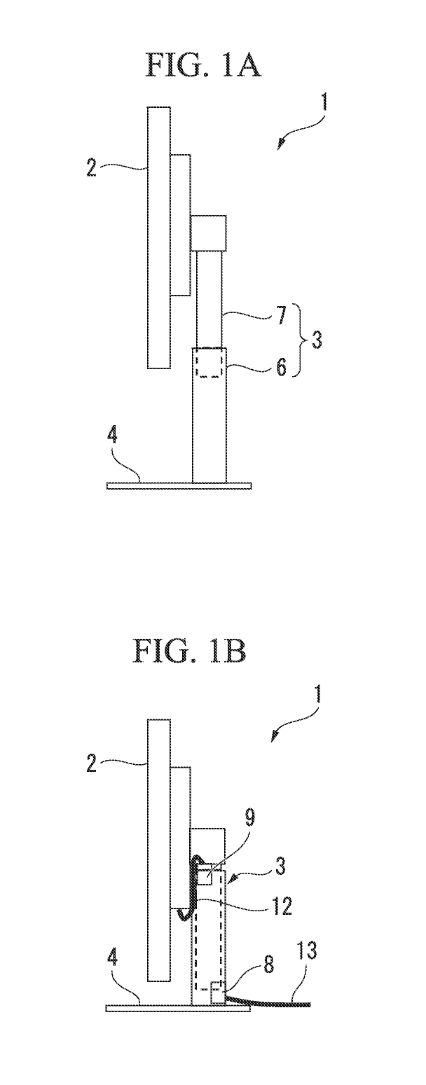

A liquid crystal display device 1 according to the first embodiment of the present invention will be described with reference to FIGS. 1A to 5B.

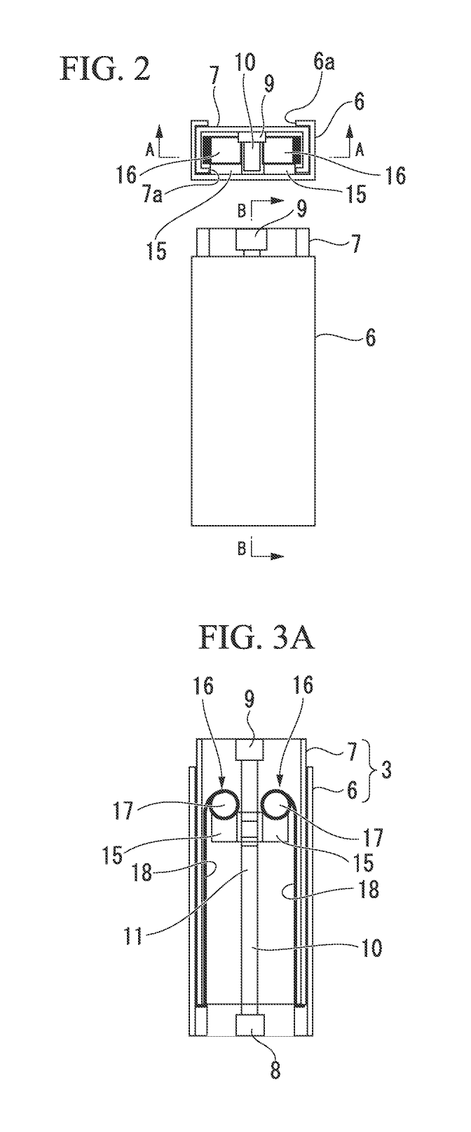

The liquid crystal display device 1 shown in FIGS. 1A and 1B includes a liquid crystal display 2 having a liquid crystal display screen, a height adjustment stand 3 having a height adjustment function, and a stand base 4 configured to support the height adjustment stand 3. The height adjustment stand 3 includes a fixed part 6 connected to the stand base 4 and a moving part 7 which can be moved up or down along with the fixed part 6 while supporting the liquid crystal display 2. As shown in FIG. 2, both the fixed part 6 and the moving part 7 have a cylindrical shape, e.g. a rectangular cylinder, wherein the moving part 7 can be moved in a sliding manner inside the fixed part 6.

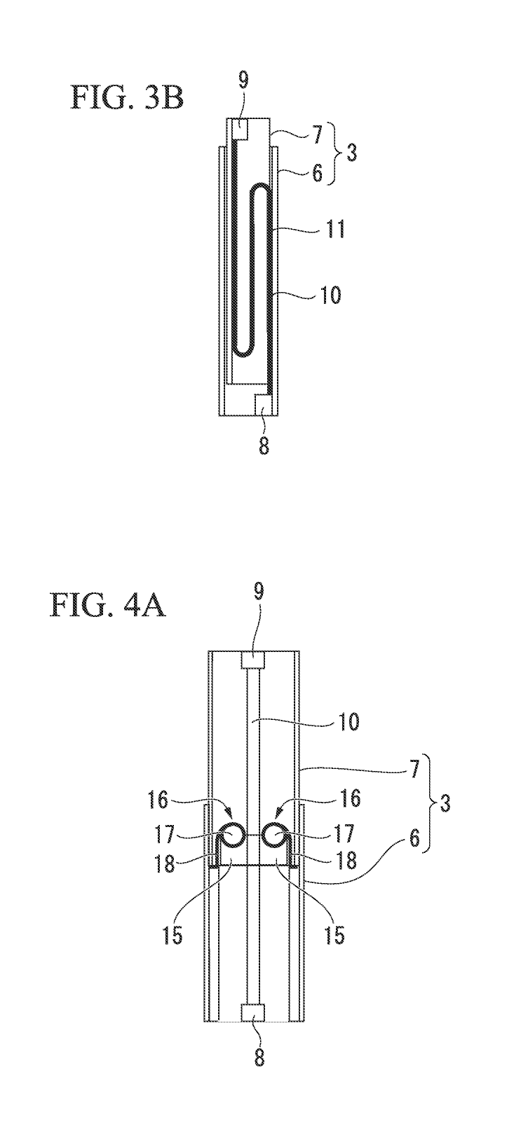

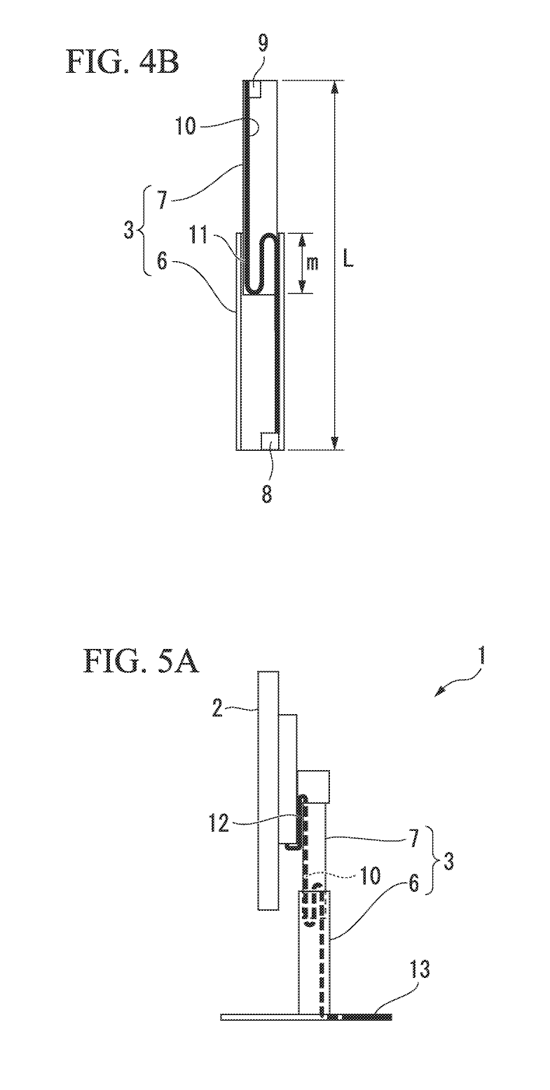

In longitudinal-sectional views of FIG. 2 shown in FIGS. 3A, 3B and FIGS. 4A, 4B, a lower connector 8 is fixed to the lower end of the internal face of the fixed part 6 in the height adjustment stand 3, while an upper connector 9 is fixed to the upper end of the internal face of the moving part 7. A flat cable 10 having an S-shaped curved part 11 is connected to at least the intermediate positions of the lower connector 8 of the fixed part 6 and the upper connector 9 of the moving part 7.

As shown in FIG. 1B, the upper connector 9 is electrically connected to the liquid crystal display 2 via a first cable 12 configured to supply power or transmit signals. The lower connector 8 is electrically connected to a power source or a signal supply source such as a computer and a keyboard, all of which are not shown, via a second cable 13 configured to supply power or transmit signals.

The flat cable 10 having elasticity is shaped as a single long and thin band when it is not incorporated into the height adjustment stand 3. When incorporated into the height adjustment stand 3, the flat cable 10 forms the S-shaped curved part 11 so as to allow for the upward/downward movement within a range of elasticity due to an S-shape. That is, the flat cable 10 is formed to be longer than the maximum length of the height adjustment stand 3 being located at the ascending position so as to maintain a certain length of the S-shaped curved part 11 between the descending position, at which the moving part 7 descends down to the lower end position as shown in FIGS. 3A and 3B, and the ascending position, at which the moving part ascends up to the upper end position as shown in FIGS. 4A and 4B. When the height adjustment stand 3 is moved up or down, the flat cable 10 is expanded or reduced within a range of variations of the length of the S-shaped curved part 11. The flat cable 10 is structured to align a plurality of lines in a perpendicular direction to the expansion/reduction direction; hence, the flat cable 10 may not be twisted in a perpendicular direction to the expansion/reduction direction when being expanded or reduced. That is, the S-shaped structure may not be disarranged or deformed due to the upward/downward movement of the height adjustment stand 3.

The flat cable 10 is formed to maintain substantially the same length of the S-shaped curved part 11 as the overlapped length between the fixed part 6 and the moving part 7 when the moving part 7 is located at the ascending position (or the upper end position) shown in FIG. 4B. For example, it is possible to assume that the length m of the curved part 11 of the flat cable 10 accounts for about 20% of the maximum length L of the height adjustment stand 3. That is, the length of the flat cable 10 is determined to form the S-shaped curved part 11 even when the moving part 7 is pulled out from the fixed part 6 with the maximum length (i.e. when the height adjustment stand 3 is maximally extended). Thus, it is possible to prevent the S-shaped curved part 11 from being changed to another shape although the length of the S-shaped curved part 11 is varied while the height adjustment stand 3 is being reduced in height on the above condition.

The flat cable 10 is designed to form the S-shaped curved part 11 without forming any contacts thereof or to preferably form the S-shape with three lines being positioned in parallel to each other on the condition that the moving part 7 is located at the descending position (or the lower end position) shown in FIG. 3B. At the ascending position and the descending position shown in FIGS. 3B and 4B, the S-shaped curved part 11 is placed in a non-contact condition due to a small gap with the internal wall of the fixed part 6 and a small gap with the internal wall of the moving part 7. Thus, it is possible to prevent the mutual interference of the S-shaped curved part 11 of the flat cable 10 irrespective of the upward/downward movement of the moving part 7, and therefore the flat cable 10 can be smoothly moved up or down without causing any interference with the internal walls of the fixed part 6 and the moving part 7.

The height adjustment stand 3 employs the fixed part 6 and the moving part 7, each having a rectangular cylinder shape in plan view as shown in FIG. 2, wherein an opening 6a is formed on one face of the fixed part 6 while an opening 7a is formed on the face of the moving part 7 located opposite to the opening 6a of the fixed part 6 on the condition that the moving part 7 is engaged inside the fixed part 6 in a sliding manner. A pair of guides 15 is fixed to the face opposite to the opening 6a of the fixed part 6 in such a way that the guides 15 slightly project inside the moving part 7 via the opening 7a. In the example shown in FIG. 2, a pair of guides 15 is positioned at both ends of the flat cable 10. The guides 15 are supported by constant-force springs (or constant springs) 16 serving as elastic members. Owing to the constant-force springs 16, it is possible to stationarily hold the liquid crystal display 2 and the moving part 7 at an arbitrary height relative to the fixed part 6, thus demonstrating a height adjustment function.

The constant-force spring 16 includes a band-shaped spring 18 wound about a drum 17, which is thus supported by the guide 15. One end of the spring 18 being wound is fed from the drum 17 and connected to one end of the moving part 7, e.g. the lower end; hence, it is possible to hold the liquid crystal display 2 and the moving part 7 at an arbitrary height depending on the length of the spring 18 being fed from the drum 17. As shown in FIGS. 3A and 4A, the constant-force spring 16 is supported by the position proximate to the upper end of the fixed part 6.

Next, the operation of the liquid crystal display device 1 equipped with the height adjustment stand 3 having the above structure according to the first embodiment will be described below.

In FIGS. 1B, 3A, and 3B, the height adjustment stand 3 of the liquid crystal display device 1 is held at the descending position corresponding to the lowest height. In the height adjustment stand 3, the entirety of the moving part 7 is substantially kept inside the fixed part 6, in which the flat cable 10 is bent and held with a long length of the S-shaped curved part 11. In this condition, the constant-force springs 16 are each held at the position to feed the longest length of the spring 18.

When the liquid crystal display 2 and the moving part 7 are moved upwardly in the above condition, the flat cable 10 is extended while reducing the length of the S-shaped curved part 11. At the same time, the springs 18 of the constant-force springs 16 are being wound about the drums 17. The constant-force springs 16 may support and hold the liquid crystal display 2 and the moving part 7 at an arbitrary position to counterbalance with the weights of the liquid crystal display 2 and the moving part 7.

When the liquid crystal display 2 and the moving part 7 are pulled up to the upper end position, as shown in FIGS. 4A and 4B, the height adjustment stand 3 of the liquid crystal display device 1 is elevated and held at the highest position. At this position, a large part of the moving part 7 is projected outside the fixed part 6 while the flat cable 10 inside the fixed part 6 is bent and held with the shortest length of the S-shaped curved part 11. In this condition, the constant-force springs 16 are each held at the position that the spring 18 is maximally wound about the drum 17.

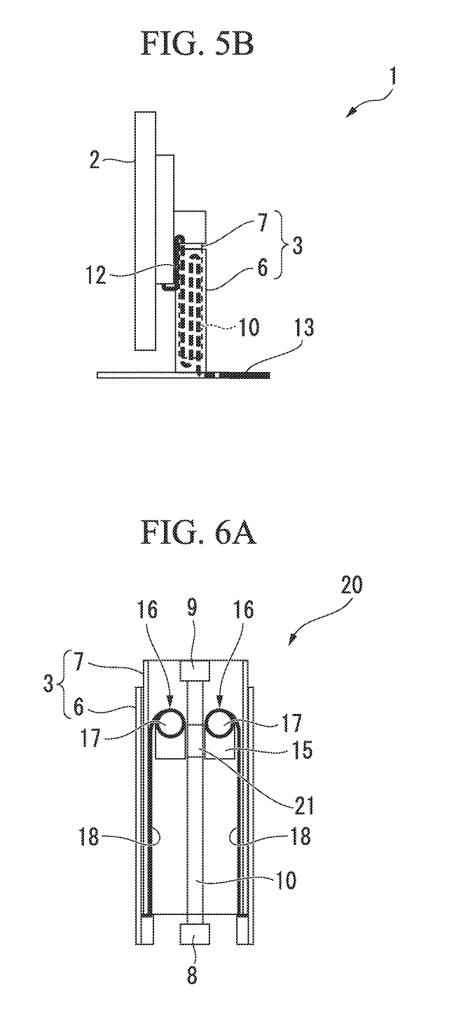

As shown in FIGS. 5A and 5B, the upper and lower ends of the flat cable 10 are electrically connected to the upper connector 9 and the lower connector 8. Even when the height adjustment stand 3 is operated to adjust the height between the upper end position and the lower end position, it is possible to maintain an electric connection with the flat cable 10 such that the S-shaped curved part 11 is being changed in length depending upon height variations.

Both the first cable 12, connected between the upper connector 9 of the moving part 7 and the liquid crystal display 2, and the second cable 13, connected between the power source and the lower connector 8, are not expanded or reduced irrespective of height variations of the height adjustment stand 3; hence, it is possible to demonstrate good operability and good exterior appearance without being influenced by height variations.

As described above, the first embodiment is directed to the liquid crystal display device 1 equipped with the height adjustment stand 3 in which the flat cable 10 having the S-shaped curved part 11 is incorporated in the height adjustment stand 3 such that the length of the S-shaped curved part 11 is varied depending on height variations of the height adjustment stand 3. This eliminates the necessity of arranging cables outside the height adjustment stand 3 and the necessity of providing components such as a cover configured to enclose cables, thus reducing the size of the height adjustment stand 3.

Additionally, the opposite ends of the flat cable 10 installed in the height adjustment stand 3 are connected to the upper connector 9 and the lower connector 8. In a height adjustment, it is possible to maintain the S-shape of the flat cable 10 without causing any kinks of the flat cable 10; hence, it is possible to stabilize the entire shape of the flat cable 10 while maintaining an electric connection irrespective of height variations. For this reason, it is possible to achieve a simple structure without providing additional components such as cable guides.

In a height adjustment, cables arranged outside the height adjustment stand 3 may interfere with the liquid crystal display device 1. In the liquid crystal display device 1 of the present embodiment, the constant length is secured for each of the first cable 12 connected to the liquid crystal display 2 located outside the height adjustment stand 3 and the second cable 13 connected to the power source, and therefore it is possible to prevent the cables 10, 12, and 13 from interfering with the liquid crystal display device 1. Thus, it is possible to demonstrate a good operability and a good exterior appearance with the height adjustment stand 3.

The present invention is not necessarily limited to the display device 1 equipped with the height adjustment stand 3 according to the foregoing embodiment; hence, it is possible to appropriately employ any variations without departing from the subject matter of the present invention.

The following descriptions are made with respect to other embodiments in which parts or members identical to those of the first embodiment are denoted using the same reference signs.

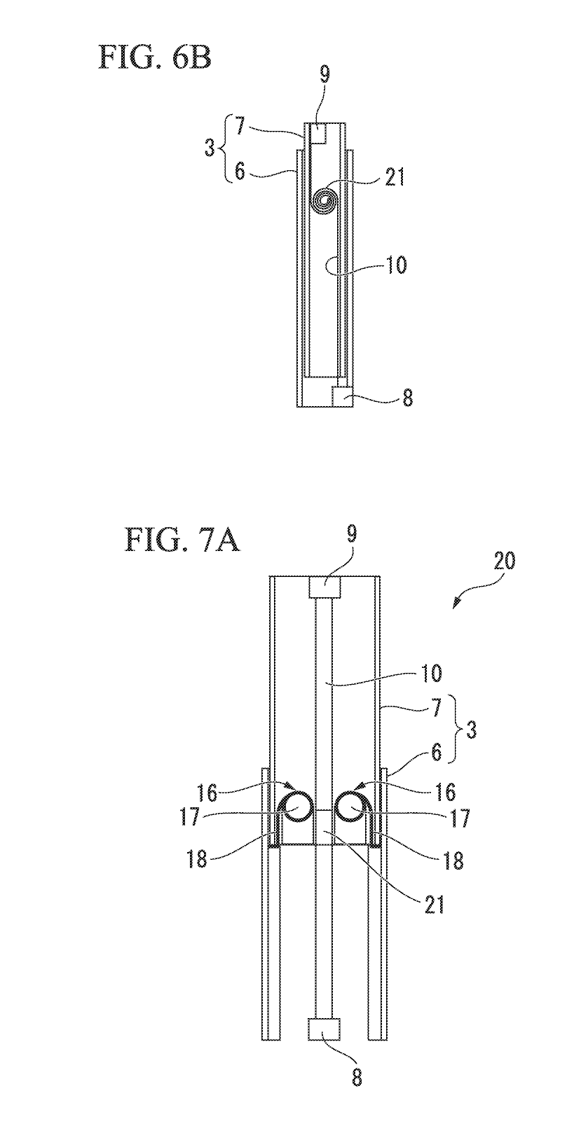

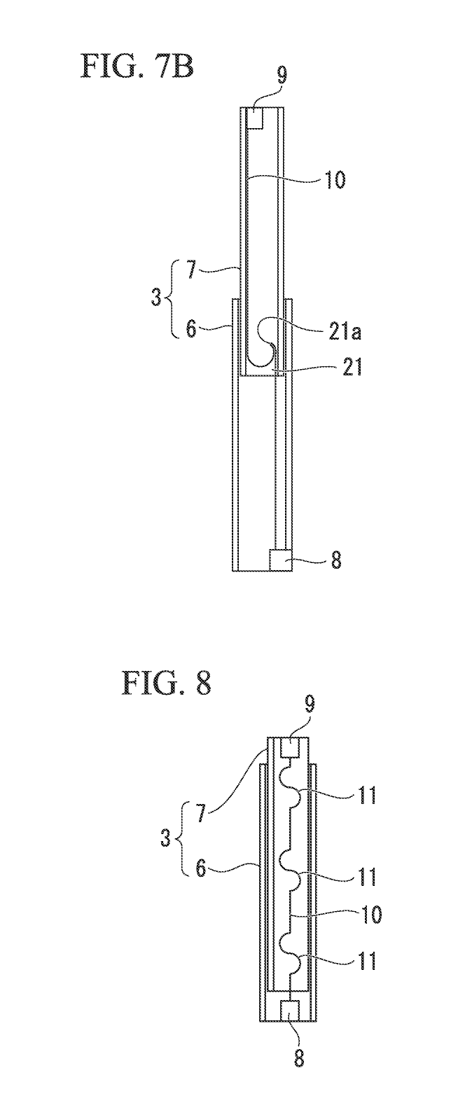

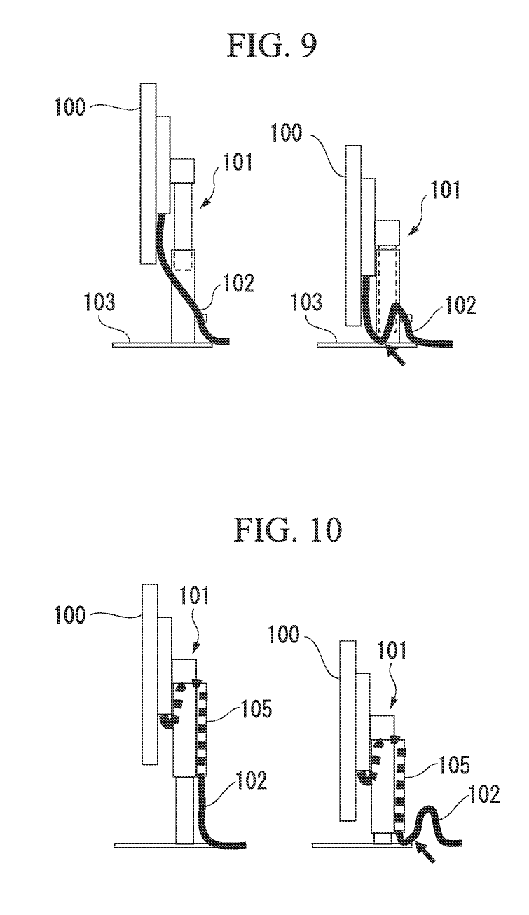

FIGS. 6A, 6B and FIGS. 7A, 7B are cross-sectional views showing the display device 1 equipped with a height adjustment stand 20 according to the second embodiment of the present invention.

In the second embodiment, the height adjustment stand 20 includes the curved part of the flat cable 10 having a different shape than the S-shaped curved part 11 of the first embodiment although the second embodiment is similar to the first embodiment in other parts.

As shown in FIGS. 6A and 7A, similar to the first embodiment, the flat cable 10 is arranged between a pair of constant-force springs 16. As shown in FIGS. 7A and 7B, the intermediate points of the upper and lower connectors 9 and 8 in the length direction of the flat cable 10 are electrically connected together via a folded part 21a which is folded or curved in a U-shape. The flat cable 10 includes a helically-bent part 21 which is formed by bending the opposite ends of the folded part 21a, serving as an internal terminal, in a double-helical shape (see FIG. 6B).

As shown in FIG. 6B, when the upper connector 9 may maximally approaches the lower connector 8 at the descending position at which a large part of the moving part 7 being descending down is held inside the fixed part 6, the flat cable 10 is wound about the helically-bent part 21 centering around the folded part 21a due to elasticity. As shown in FIG. 7B, when the moving part 7 is maximally elevated above the fixed part 6 at the ascending position, the upper connector 9 is maximally distanced from the lower connector 8, and therefore the flat cable 10 is extended between the upper and lower connectors 9 and 8 and thus partially curved in the proximity of the folded part 21a with a semicircle length or less.

At the descending position corresponding to the lowest height of the height adjustment stand 20 in the display device 1 of the second embodiment, as shown in FIG. 6A, the entirety of the moving part 7 of the height adjustment stand 20 is substantially kept inside the fixed part 6, in which the flat cable 10 is wound about the helically-bent part 21 centering around the folded part 21a. At this position, it is possible to maximally feed the spring 18 of the constant-force spring 16 shown in FIG. 6A.

When the liquid crystal display 2 and the moving part 7 are pulled up in the above condition, it is possible to extract the wound part of the helically-bent part 21 of the flat cable 10 upwardly and downwardly, thus reducing the number of turns of the helically-bent part 21. At the same time, the springs 18 of the constant-force springs 16 are being wound about the drums 17. Owing to the constant-force springs 16, it is possible to stationarily locate the liquid crystal display 2 and the moving part 7 at an arbitrary position to counterbalance with the weights of the liquid crystal display 2 and the moving part 7.

When the liquid crystal display 2 and the moving part 7 are elevated up to the ascending position, as shown in FIGS. 7A and 7B, it is possible to raise and hold the height adjustment stand 20 of the liquid crystal display device 1 at the upper end position. At this position, a large part of the moving part 7 is projected outside the fixed part 6 in which the flat cable 10 is extracted and held to secure the lowest number of turns with the folded part 21a of the helically-bent part 21. In this condition, the constant-force springs 16 are each held at the position that the spring 18 is maximally wound about the drum 17.

Since the upper and lower ends of the flat cable 10 are electrically connected to the upper connector 9 and the lower connector 8, it is possible to cope with height variations due to the height adjustment of the height adjustment stand 20 by changing the number of turns of the helically-bent part 21 centering around the folded part 21a, thus securing an electric connection with the flat cable 10.

Both the first cable 12, connected between the upper connector 9 of the moving part 7 and the liquid crystal display 2, and the second cable 13, connected between the power source and the lower connector 8, are not expanded or reduced irrespective of height variations of the height adjustment stand 20; hence, it is possible to demonstrate a good exterior appearance without being influences by height variations.

The liquid crystal display device 1 is described in connection with the display devices equipped with the height adjustment stands 3 and 20 according to the foregoing embodiments; but the present invention is not necessarily limited to the liquid crystal display device 1; hence, it is possible to apply the height adjustment stands 3 and 20 to various types of display devices such as plasma display devices and organic LED display devices.

The foregoing embodiments employ a pair of constant-force springs 16 which is configured to hold the height adjustment stands 3, 20 at arbitrary heights and which is incorporated into the opposite ends of the flat cable 10; however, it is possible to employ a single constant-force spring 16.

The foregoing embodiments employ the flat cable 10, serving as a wiring cable, which is connected between the upper connector 9 and the lower connector 8 in the height adjustment stands 3 and 20; however, the wiring cable of the present invention is not necessarily limited to the flat cable 10; hence, it is possible to employ linear cables, power cables, and signal transmission cables having arbitrary sectional shapes.

The flat cable 10 serving as a wiring cable includes the S-shaped curved part 11 which is formed in a perpendicular direction to the upward/downward movement direction (or the height direction) of the height adjustment stands 3, 20. Instead, it is possible to adopt a variation of FIG. 8 using the flat cable 10 including one or more S-shaped curved parts 11 along the upward/downward movement direction of the height adjustment stands 3, 20. In this case, it is possible to partially expand or reduce a plurality of S-shaped curved parts 11 depending on height variations of the height adjustment stand 3 since the fixed part and the moving part 7 have relatively small diameters.

The flat cable 10 serving as a wiring cable may include any shapes of curved parts which are not necessarily limited to the S-shaped curved part 11 and the helically-bent part 21; hence, the flat cable 10 can be formed in an accordion-shape or other arbitrary shapes such as curved or bent shapes.

In the foregoing embodiments, both the S-shaped curved part 11 and the helically-bent part 21 are arranged in the overlapped area between the fixed part 6 and the moving part 7; however, it is possible to form the fixed part and the moving part 7 in a one-side area externally of the overlapped area. Alternatively, it is possible to form the fixed part 6 and the moving part 7 in a one-side area alone.

### INDUSTRIAL APPLICABILITY

The present invention provides a display device equipped with a height adjustment stand which is able to secure an electric conduction with a flat cable being expanded or reduced depending on height variations of the height adjustment stand without any force since the upper and lower ends of the flat cable, installed in the height adjustment stand configured to support a display such as a liquid crystal display, are connected to the upper and lower connectors while a curved part such as an S-shaped curved part and a helically-bent part is formed at the intermediate position of the flat cable.

### REFERENCE SIGNS LIST

1 liquid crystal display device
2 display
3, 20 height adjustment stand
6 fixed part
7 moving part
8 lower connector
9 upper connector
10 flat cable
11 S-shaped curved part
12 first cable
13 second cable
15 guide
16 constant-force spring
17 drum
18 spring
21 helically-bent part
21a folded part

1. A display device equipped with a height adjustment stand, corresponding to a display device including a display having a display screen and a height adjustment stand which is connected to the display so as to perform height adjustment,
wherein the height adjustment stand includes a fixed part attached to a base, a moving part which is connected to the display and movable up or down inside the fixed part, and a wiring cable arranged inside the fixed part and the moving part, and
wherein the wiring cable has a curved part which is expandable or reducible inside the fixed part and/or the moving part and which is connected between an end of the fixed part and an end of the moving part.

2. The display device equipped with a height adjustment stand according to claim 1, wherein the curved part of the wiring cable is an S-shaped curved part or a helically-bent part.

3. The display device equipped with a height adjustment stand according to claim 1, wherein the wiring cable is set to a length leaving the curved part when the moving part is extracted from the fixed part with a maximum length.

4. The display device equipped with a height adjustment stand according to claim 1, wherein the end of the fixed part and the end of the moving part connected to the wiring cable are connectors.

5. The display device equipped with a height adjustment stand according to claim 1, wherein the fixed part and the moving part are connected together via a constant-force spring, thus carrying out height adjustment.

6. The display device equipped with a height adjustment stand according to claim 5, wherein the constant-force spring includes a spring wound about a drum engaged with the fixed part while an end of the spring is engaged with the moving part.

7. The display device equipped with a height adjustment stand according to claim 5, further comprising a plurality of constant-force springs installed inside the fixed part and the moving part, wherein the wiring cable is aligned between the plurality of constant-force springs.

8. The display device equipped with a height adjustment stand according to claim 1, wherein the end of the moving part is furnished with a first cable electrically connected to the display device while the end of the moving part is furnished with a second cable electrically connected to a power source or a signal supply source.
